(19) United States
(12) Patent Application Publication
(10) Pub. No.: US 2026/0111091 A1
(43) Pub. Date: Apr. 23, 2026

(54) REFLECTIVE DISPLAY

(71) Applicant: Wacom Co., Ltd., Saitama (JP)

(72) Inventors: Hiroshi MIZUHASHI, Saitama (JP); Joo Hoon LEE, Saitama (JP); Fumitaka GOTO, Saitama (JP)

(73) Assignee: Wacom Co., Ltd., Saitama (JP)

(21) Appl. No.: 19/412,614

(22) Filed: Dec. 8, 2025

Related U.S. Application Data
(63) Continuation of application No. PCT/JP2024/015679, filed on Apr. 22, 2024.

(30) Foreign Application Priority Data
Jul. 3, 2023 (JP) 2023-109117

(51) Int. Cl. G06F 3/046; G02F 1/1333; G02F 1/167; G06F 3/041; H10D 86/40

(52) U.S. Cl. CPC G06F 3/046; G06F 3/04164; H10D 86/441; G02F 1/13338; G02F 1/167; G06F 3/0412; G06F 2203/04102

(57) ABSTRACT

A reflective display includes a cover layer that has an operation surface on which a position indicator including an inductor is operated, a reflective display layer that includes a plurality of reflective elements each of which reflects, with a set gradation, light incident from the cover layer, a backplane that is provided at a position farther than the reflective display layer as viewed from the operation surface, and a common electrode layer that includes a common electrode provided between the cover layer and the reflective display layer. The backplane has, in a display area, a plurality of pixel electrodes, a plurality of data lines, and a plurality of first electromagnetic induction sensor electrodes. The plurality of first electromagnetic induction sensor electrodes are used for detecting the position of the position indicator in the operation surface by generating electromagnetic induction action with the inductor.

### BACKGROUND

### Technical Field

The present disclosure relates to a reflective display, and particularly to a reflective display that is compatible with pen input based on an electromagnetic resonance (EMR) system.

### Description of the Related Art

Electronic paper is a type of reflective display for displaying an image by using external light. An example of a structure of the electronic paper is disclosed in Japanese Patent Laid-open No. 2015-165570, U.S. Pat. No. 8,749,476, and S. E. Burns and 21 others, “A scalable manufacturing process for flexible active-matrix e-paper displays” Journal of the Society for Information Display, July 2005. As described in these documents, the electronic paper has a structure in which a light reflective layer including reflective elements such as microcapsules is sandwiched between pixel electrodes and common electrodes. The pixel electrodes are arranged on the upper surface of a backplane including pixel transistors, gate lines, data lines, and the like.

Incidentally, the inventors of the present application have studied how to make a reflective display compatible with pen input based on the EMR system. Achieving this, however, requires the arrangement of a position detection sensor on the lower side (the side far from the display surface) of the backplane of the reflective display, which increases the overall thickness, and therefore, improvements have been required.

### BRIEF SUMMARY

Thus, one of the objects of the present disclosure is to provide a reflective display that can be reduced in height while being compatible with pen input based on the EMR system.

A reflective display according to one aspect of the present disclosure includes a cover layer that has an operation surface on which a position indicator including an inductor is operated, a reflective display layer that includes a plurality of reflective elements each of which reflects, with a set gradation, light incident from the cover layer, a backplane that is provided at a position farther than the reflective display layer as viewed from the operation surface, and a common electrode layer that includes a common electrode provided between the cover layer and the reflective display layer. In a display area overlapping the plurality of reflective elements in plan view, the backplane has a plurality of pixel electrodes arranged in a matrix along a first direction and a second direction intersecting the first direction, a plurality of data lines each extending along the first direction, and a plurality of first electromagnetic induction sensor electrodes each extending along the first direction. The plurality of first electromagnetic induction sensor electrodes are used for detecting a position of the position indicator in the operation surface by generating electromagnetic induction action with the inductor.

A reflective display according to another aspect of the present disclosure includes a cover layer that has an operation surface on which a position indicator including an inductor is operated, a reflective display layer that includes a plurality of reflective elements each of which reflects, with a set gradation, light incident from the cover layer, a backplane that is provided at a position farther than the reflective display layer as viewed from the operation surface, and a common electrode that is provided between the cover layer and the reflective display layer. In a display area overlapping the plurality of reflective elements in plan view, the backplane has a plurality of pixel electrodes arranged in a matrix along a first direction and a second direction intersecting the first direction, a plurality of gate lines each extending along the second direction, and a plurality of second electromagnetic induction sensor electrodes each extending along the second direction. The plurality of second electromagnetic induction sensor electrodes are used for detecting a position of the position indicator in the operation surface by generating electromagnetic induction action with the inductor.

A reflective display according to still another aspect of the present disclosure includes a cover layer that has an operation surface on which a position indicator including an inductor is operated, a reflective display layer that includes a plurality of reflective elements each of which reflects, with a set gradation, light incident from the cover layer, a backplane that is provided at a position farther than the reflective display layer as viewed from the operation surface, and a common electrode that is provided between the cover layer and the reflective display layer. The backplane has, in a display area overlapping the plurality of reflective elements in plan view, a plurality of pixel electrodes arranged in a matrix along a first direction and a second direction intersecting the first direction and a plurality of linear conductors each extending along the first direction. The plurality of linear conductors are used, in a time-division manner, as either a plurality of data lines used for supplying data signals to the pixel electrodes or a plurality of first electromagnetic induction sensor electrodes used for detecting a position of the position indicator in the operation surface by generating electromagnetic induction action with the inductor.

According to the present disclosure, at least either the plurality of first electromagnetic induction sensor electrodes or the plurality of second electromagnetic induction sensor electrodes are provided in the backplane, which makes it possible to reduce the height of the reflective display that is compatible with pen input based on the EMR system.

### BRIEF DESCRIPTION OF THE SEVERAL VIEWS OF THE DRAWINGS

FIG. 1 is a diagram depicting a configuration of a computer according to a first embodiment of the present disclosure;

FIG. 2 is a diagram depicting a layer structure of a reflective display;

FIG. 3 is a circuit diagram of the reflective display;

FIG. 4 is a diagram depicting a positional relation of various types of wires included in the reflective display;

FIG. 5 is a diagram for explaining processing performed by a sensor controller to detect the position of a pen by using sensor electrodes;

FIG. 6 is a diagram schematically depicting a planar structure of a portion corresponding to the circuit diagram of FIG. 3 in a circuit layer;

FIG. 7 is a schematic cross-sectional view of a backplane corresponding to the line A-A depicted in FIG. 6;

FIG. 8 is a diagram schematically depicting a planar structure of a portion corresponding to the circuit diagram of FIG. 3 in a circuit layer included in a computer according to a second embodiment of the present disclosure;

FIG. 9 is a schematic cross-sectional view of the backplane corresponding to the line B-B depicted in FIG. 8;

FIG. 10 is a diagram depicting a positional relation of various types of wires included in a reflective display according to the second embodiment of the present disclosure;

FIG. 11 is a diagram schematically depicting a planar structure of a portion corresponding to the circuit diagram of FIG. 3 in a circuit layer included in a computer according to a third embodiment of the present disclosure;

FIG. 12 is a schematic cross-sectional view of the backplane corresponding to the line C-C depicted in FIG. 11;

FIG. 13 is a diagram depicting a positional relation of various types of wires included in a reflective display according to a fourth embodiment of the present disclosure;

FIG. 14 is a diagram schematically depicting a planar structure of a portion corresponding to the circuit diagram of FIG. 3 in a circuit layer included in a computer according to the fourth embodiment of the present disclosure;

FIG. 15 is a schematic cross-sectional view of the backplane corresponding to the line D-D depicted in FIG. 14;

FIG. 16 is a diagram depicting a positional relation of various types of wires included in a reflective display according to a fifth embodiment of the present disclosure;

FIGS. 17A and 17B are diagrams for explaining processing performed by a sensor controller according to the fifth embodiment of the present disclosure to detect the position of the pen by using the sensor electrodes;

FIGS. 18A and 18B are diagrams for explaining processing performed by a sensor controller according to a first modified example of the fifth embodiment of the present disclosure;

FIGS. 19A and 19B are diagrams for explaining processing performed by a sensor controller according to a second modified example of the fifth embodiment of the present disclosure;

FIG. 20 is a diagram depicting an example of a layer structure of the reflective display in the case where the sensor electrodes are arranged in a layer other than the circuit layer;

FIG. 21 is a diagram depicting an example of a layer structure of the reflective display in the case where the sensor electrodes are arranged in a layer other than the circuit layer; and

FIG. 22 is a diagram depicting a layer structure of the reflective display in the case where both types of the sensor electrodes are used for receiving a reception signal.

### DETAILED DESCRIPTION

Hereinafter, embodiments of the present disclosure will be described in detail with reference to the accompanying drawings.

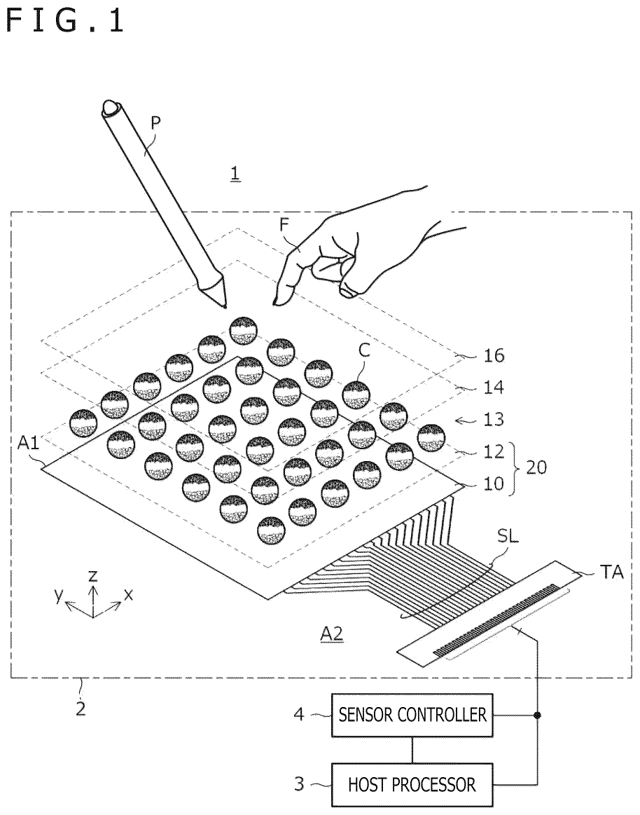

FIG. 1 is a diagram depicting a configuration of a computer 1 according to a first embodiment of the present disclosure. As depicted in FIG. 1, the computer 1 according to the present embodiment has a reflective display 2, a host processor 3, and a sensor controller 4.

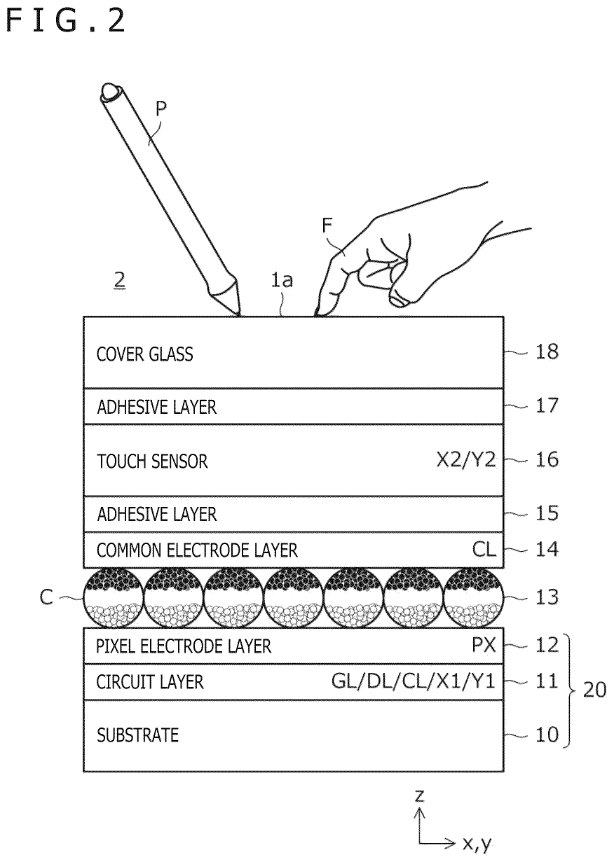

FIG. 2 is a diagram depicting a layer structure of the reflective display 2. As depicted in FIG. 2, the reflective display 2 has a substrate 10, a circuit layer 11, a pixel electrode layer 12, a reflective display layer 13, a common electrode layer 14, an adhesive layer 15, a touch sensor 16, an adhesive layer 17, and a cover glass 18 (cover layer). Among these, the substrate 10, the circuit layer 11, and the pixel electrode layer 12 configure a backplane 20 of the reflective display 2. In addition, the surface of the cover glass 18 serves as a display surface of the reflective display 2 and forms an operation surface 1a on which input by a pen P (position indicator) (pen input) and input by a finger F (touch input) are performed. It should be noted that FIG. 1 illustrates only a portion of the layer structure depicted in FIG. 2.

As will be described later in detail, the circuit layer 11 is provided with a plurality of gate lines GL, a plurality of data lines DL, a plurality of common potential lines CL, a plurality of sensor electrodes X1, and a plurality of sensor electrodes Y1. In addition, the pixel electrode layer 12 is provided with a plurality of pixel electrodes PX, the common electrode layer 14 is provided with one or more common potential lines CL (common electrodes), and the touch sensor 16 is provided with sensor electrodes X2 and Y2.

Each of the plurality of sensor electrodes X1 and Y1 is an electromagnetic induction sensor electrode used for detecting the position of the pen P according to an EMR system and generates electromagnetic induction action with an inductor configuring a resonance circuit provided in the pen P. In addition, each of the sensor electrodes X2 and Y2 is an electric field sensor electrode used for detecting the position of the finger F according to a capacitance system. A predetermined common potential (for example, ground potential) is supplied from the host processor 3 to the common potential lines CL, i.e., the common potential lines CL in the circuit layer 11 and the common potential lines CL in the common electrode layer 14. The common potential lines CL in the common electrode layer 14 and the sensor electrodes X2 and Y2 each include a transparent conductive film such as indium tin oxide (ITO) so as not to interfere with the display of the reflective display 2.

The plurality of pixel electrodes PX included in the pixel electrode layer 12 are arranged in a matrix along an x direction and a y direction (the direction intersecting the x direction). A plurality of reflective elements C are arranged in the reflective display layer 13. Each of the reflective elements C is an element that reflects light incident from the cover glass 18, with a gradation set according to the potential of the nearest pixel electrode PX. By way of example, the reflective display 2 is electrophoretic electronic paper. In such a case, the reflective elements C are configured using spherical microcapsules as illustrated in FIG. 2. Alternatively, the reflective display 2 may be electronic paper using electronic liquid powder or a reflective liquid crystal display.

In the case where the reflective display 2 is electrophoretic electronic paper, oil, a plurality of white pigment elements, and a plurality of black pigment elements are sealed in the reflective element C. These white pigment elements and black pigment elements are positively and negatively charged in advance, respectively, and are capable of migrating electrophoretically in oil. When a potential is applied to a certain pixel electrode PX, the white pigment elements or black pigment elements of a quantity which corresponds to the applied potential migrate to the operation surface 1a side in the reflective element C in the vicinity of the certain pixel electrode PX. As a result of the migration, black-and-white display with a gradation (set gradation) corresponding to the potential applied to the pixel electrode PX is performed. Although not illustrated, color display can be performed if a color filter is used.

Described with reference to FIG. 1 again, a rectangular area A1 represents a display area (an area overlapping the plurality of reflective elements C in the reflective display layer 13 in plan view) of the reflective display 2. A bezel area A2 is located outside the display area A1. As depicted in FIG. 1, a plurality of wires SL and a terminal area TA including a plurality of terminals are arranged in the bezel area A2. Among these, the plurality of wires SL are provided for connecting wires and electrodes arranged in the circuit layer 11, the common electrode layer 14, and the touch sensor 16 to the terminals in the terminal area TA. It should be noted that, in order to avoid overcomplicating the drawing, FIG. 1 schematically illustrates only some of the plurality of wires SL actually provided in the reflective display 2. Each terminal in the terminal area TA is connected to the host processor 3 or the sensor controller 4 via a wire provided outside the reflective display 2.

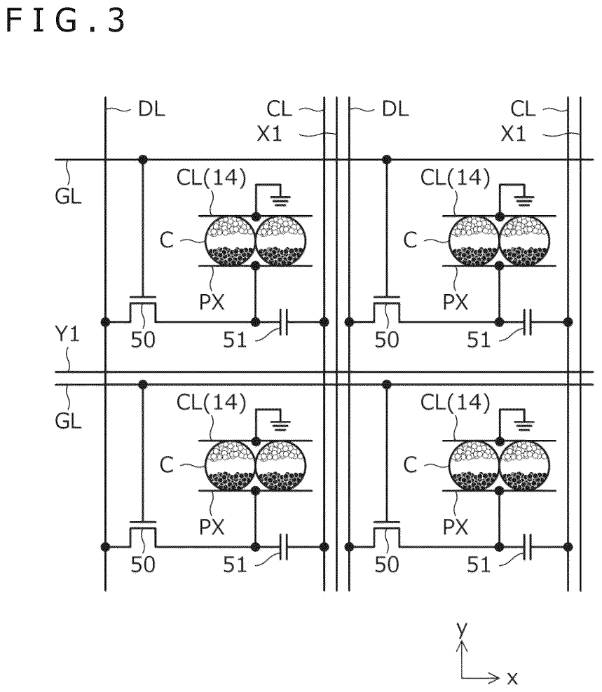

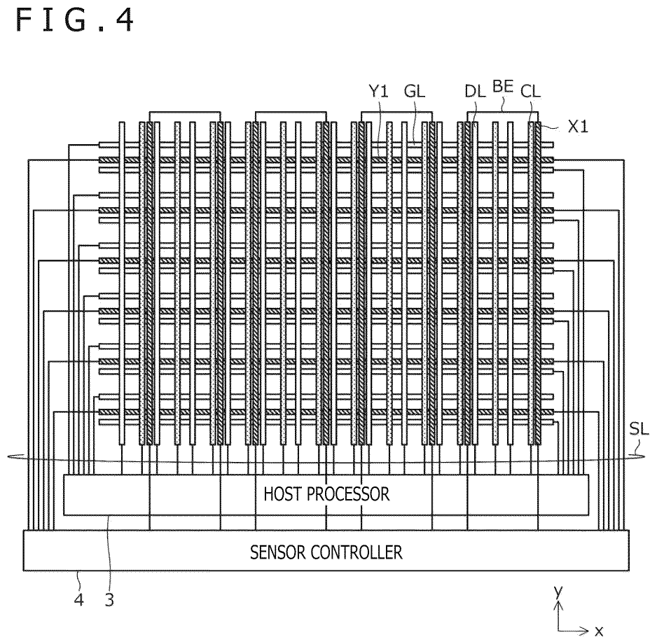

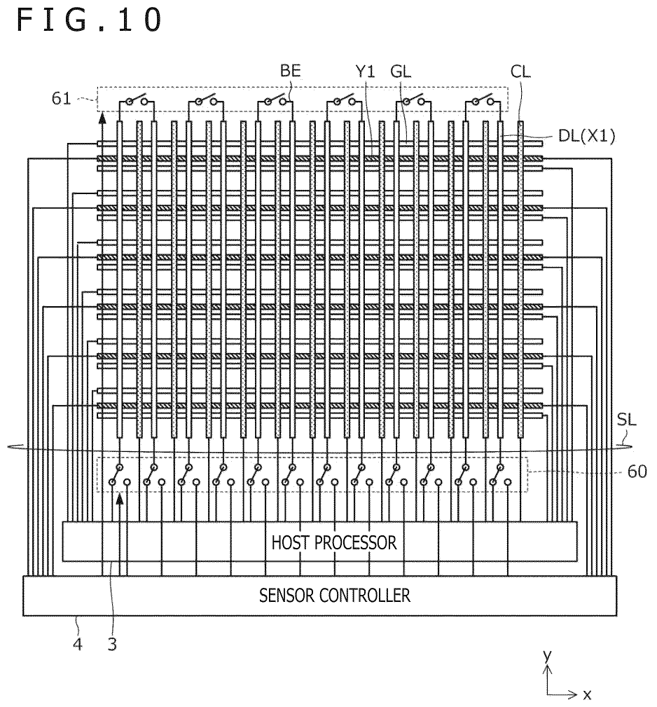

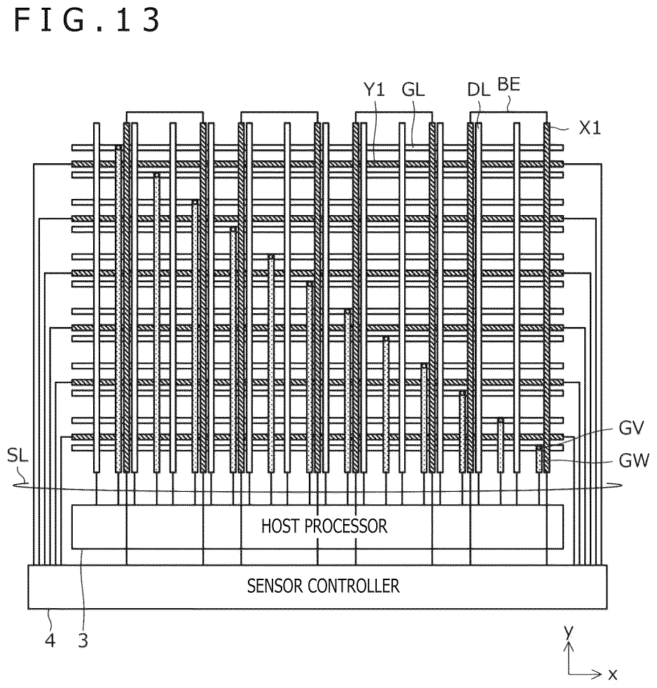

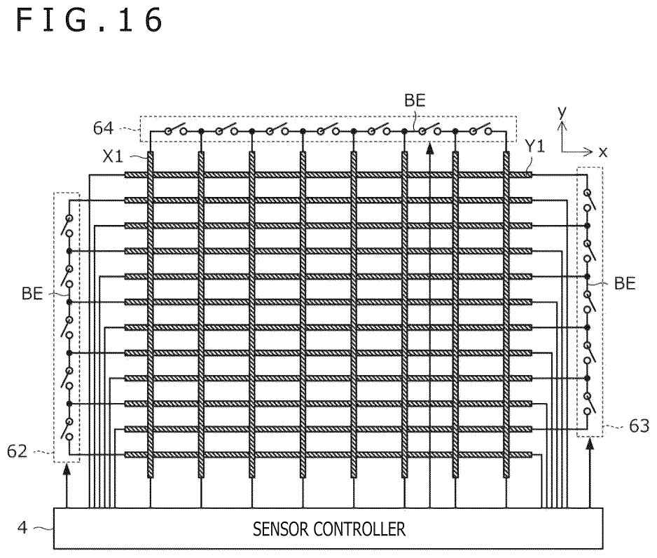

FIG. 3 is a circuit diagram of the reflective display 2. In addition, FIG. 4 is a diagram depicting a positional relation of various types of wires included in the reflective display 2. Although FIG. 3 depicts circuits for four pixel electrodes PX, more pixel electrodes PX are actually provided. In addition, although FIG. 4 depicts 12 gate lines GL, 12 data lines DL, 12 common potential lines CL, 8 sensor electrodes X1, and 6 sensor electrodes Y1, more wires are actually provided. This similarly applies to FIG. 10, FIG. 13, and FIG. 16 to FIG. 19B, which will be described later.

The gate lines GL and the sensor electrodes Y1 each extend along the x direction as depicted in FIG. 4. As depicted in FIG. 3, one gate line GL is provided for each row of the pixel electrodes PX, and one sensor electrode Y1 is provided for a plurality of rows of the pixel electrodes PX. Thus, while the number of gate lines GL and the number of rows of the pixel electrodes PX match each other, the number of sensor electrodes Y1 is smaller than the number of rows of the pixel electrodes PX. More specifically, it is preferable that the pitch of the gate line GL be several hundred micrometers and the pitch of the sensor electrode Y1 be a few millimeters.

In addition, as depicted in FIG. 4, the data lines DL, the common potential lines CL, and the sensor electrodes X1 each extend along the y direction. As depicted in FIG. 3, one data line DL and one common potential line CL are provided for each column of the pixel electrodes PX, and one sensor electrode X1 is provided for a plurality of columns of the pixel electrodes PX. Thus, while the number of data lines DL and the number of common potential lines CL each match the number of columns of the pixel electrodes PX, the number of sensor electrodes X1 is smaller than the number of columns of the pixel electrodes PX. More specifically, it is preferable that the pitch of each of the data line DL and the common potential line CL be several hundred micrometers and the pitch of the sensor electrode X1 be a few millimeters.

As depicted in FIG. 4, base electrodes BE are connected to end portions of the plurality of sensor electrodes X1 on the side far from the terminal area TA (see FIG. 1). Each of the base electrodes BE connects two sensor electrodes X1 to each other from one end side in the x direction. The base electrodes BE are arranged in the bezel area A2 in plan view. This connection is made in order to form a loop coil for receiving an alternating magnetic field transmitted from the inductor in the pen P, by using the two sensor electrodes X1. The other end portion of each sensor electrode X1 on the side near the terminal area TA is connected to the sensor controller 4 via the wire SL.

Further, opposite ends of each sensor electrode Y1 are connected to the sensor controller 4 via the wires SL, while either a first end or a second end of each gate line GL is connected to the host processor 3 via the wire SL such that the connection of the first end alternates with the connection of the second end when viewed in the y direction. In addition, an end portion of each data line DL and an end portion of each common potential line CL on the side near the terminal area TA are connected to the host processor 3 via the wires SL.

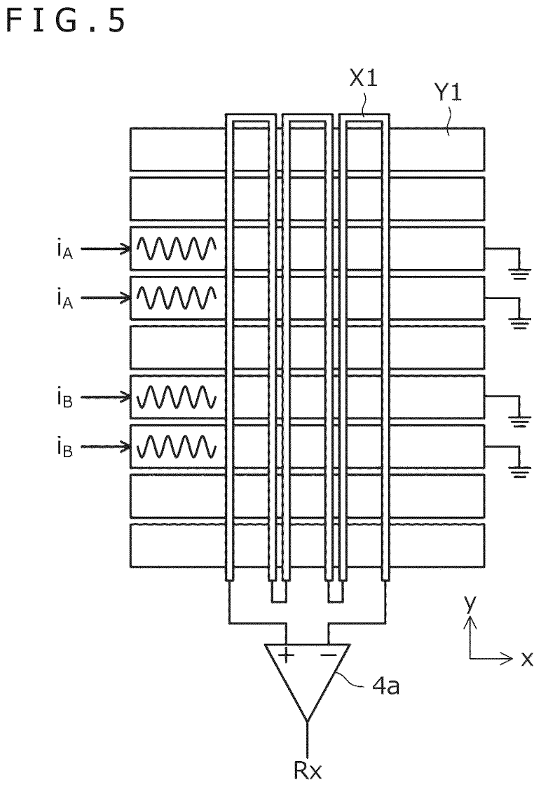

FIG. 5 is a diagram for explaining processing performed by the sensor controller 4 to detect the position of the pen P by using the sensor electrodes X1 and Y1. In this processing, the sensor controller 4 sequentially selects one of the plurality of sensor electrodes Y1 except for two sensor electrodes Y1 at each of opposite ends in the y direction. Every time the sensor controller 4 makes such a selection, it also sequentially selects one of a plurality of loop coils (each of which is formed by two sensor electrodes X1, and the same applies to the following) except for one loop coil at each of opposite ends in the x direction.

As depicted in FIG. 5, the sensor controller 4 supplies an alternating current i_{A} to one end of each of two sensor electrodes Y1 which are adjacent to the selected sensor electrode Y1 on one side, and supplies an alternating current i_{B} to one end of each of two sensor electrodes Y1 which are adjacent to the selected sensor electrode Y1 on the other side. The alternating current i_{A} is a current oscillating at a constant frequency and phase, and the alternating current i_{B} is a current obtained by inverting the phase of the alternating current i_{A}. Typical alternating currents i_{A} and i_{B} are sinusoidal signals as illustrated in FIG. 5, but may instead be rectangular wave signals. In addition, the sensor controller 4 connects, to a ground terminal, each of the other ends of the four sensor electrodes Y1 to which the alternating currents i_{A} and i_{B} are supplied. It should be noted that the other ends of the four sensor electrodes Y1 may be connected to each other instead of being connected to the ground terminal. When the sensor controller 4 performs such an operation as described above, a change in magnetic flux occurs above the selected sensor electrode Y1. Then, when the inductor of the pen P enters the magnetic flux (alternating magnetic field) that changes, electromagnetic induction action occurs between the sensor electrode Y1 and the inductor, and a change in current is generated in the inductor. As a result, an alternating magnetic field is transmitted from the pen P, and an electromotive force is generated in the sensor electrode X1 located nearby.

The sensor controller 4 has a differential amplifier 4a which is configured to connect in series the selected loop coil and the loop coils that are adjacent to the selected loop coil on both sides, between two input terminals of the differential amplifier 4a. When an electromotive force is generated in the sensor electrode X1 by the alternating magnetic field transmitted from the pen P, a current is generated in the corresponding loop coil and is supplied to the sensor controller 4 via the differential amplifier 4a. The sensor controller 4 acquires the current thus supplied from the differential amplifier 4a immediately after supplying the alternating currents i_{A} and i_{B} to the sensor electrodes Y1 for a predetermined period of time, as a reception signal Rx from the pen P which corresponds to each loop coil.

With the above processing, the sensor controller 4 acquires, for each sensor electrode Y1, the reception signal Rx received at each loop coil. The sensor controller 4 derives the distribution, in the operation surface 1a, of the signal intensities of a plurality of acquired reception signals Rx and then derives the position of the pen P on the basis of the result.

It should be noted that, while the alternating currents i_{A} and i_{B} are supplied to the sensor electrodes Y1 and the reception signals Rx are received at the sensor electrodes X1 in the example of FIG. 5, the alternating currents i_{A} and i_{B} may instead be supplied to the sensor electrodes X1, and the reception signals Rx may be received at the sensor electrodes Y1. In this case, the above-described base electrodes BE may be arranged on one end side or the other end side of the sensor electrodes Y1 to thereby use each sensor electrode Y1 as a loop coil, while one end (end portions on the side far from the terminal area TA) of the respective sensor electrodes X1 may be connected to the ground terminal in advance or connected to each other.

With reference to FIG. 3 again, a display operation of the reflective display 2 will be described. As depicted in FIG. 3, the reflective display 2 has a pixel transistor 50 and a storage capacitor 51 for each pixel electrode PX. The pixel transistor 50 has a control electrode connected to the corresponding gate line GL, a first controlled electrode connected to the corresponding data line DL, and a second controlled electrode connected to the corresponding pixel electrode PX. In addition, the storage capacitor 51 has a first electrode connected to the corresponding pixel electrode PX and a second electrode connected to the corresponding common potential line CL. With this configuration, when the host processor 3 activates a certain gate line GL, a series of pixel transistors 50 connected to the certain gate line GL is turned on, and a series of corresponding pixel electrodes PX is connected to the corresponding data line DL. Accordingly, the host processor 3 can control the set gradation of each pixel by controlling the potential of the data line DL. In addition, while the pixel transistor 50 is turned on, the potential of the data line DL is also applied to the storage capacitor 51 to charge the storage capacitor 51. Since the charge accumulated in the storage capacitor 51 by the charging is maintained even after the pixel transistor 50 is turned off, the display state of each pixel is maintained even while the corresponding gate line GL is inactive.

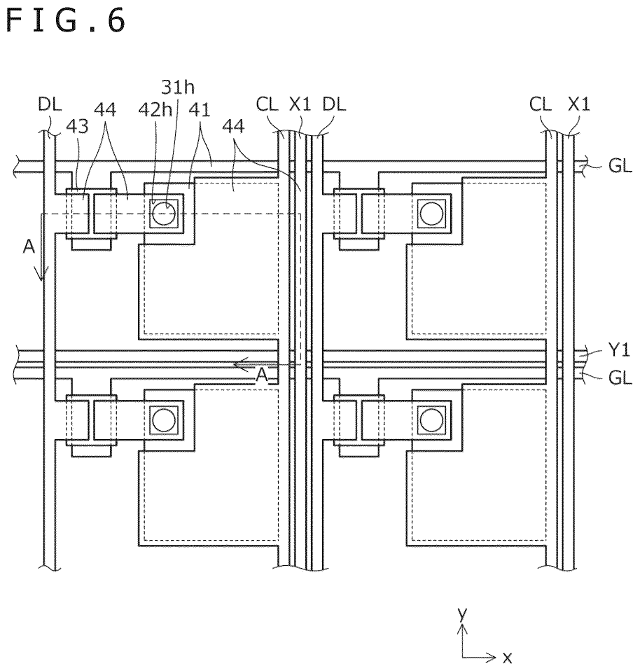

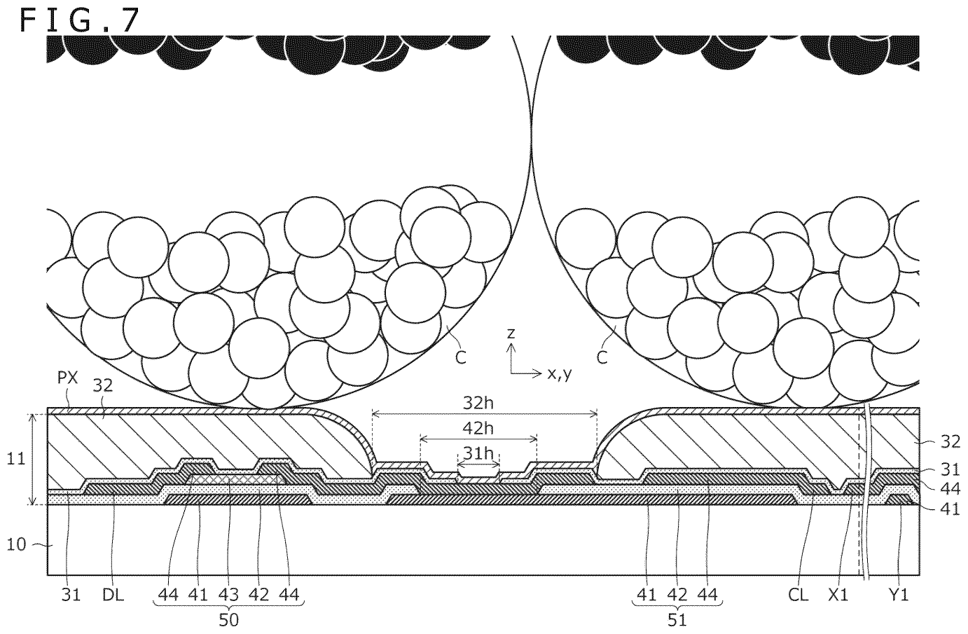

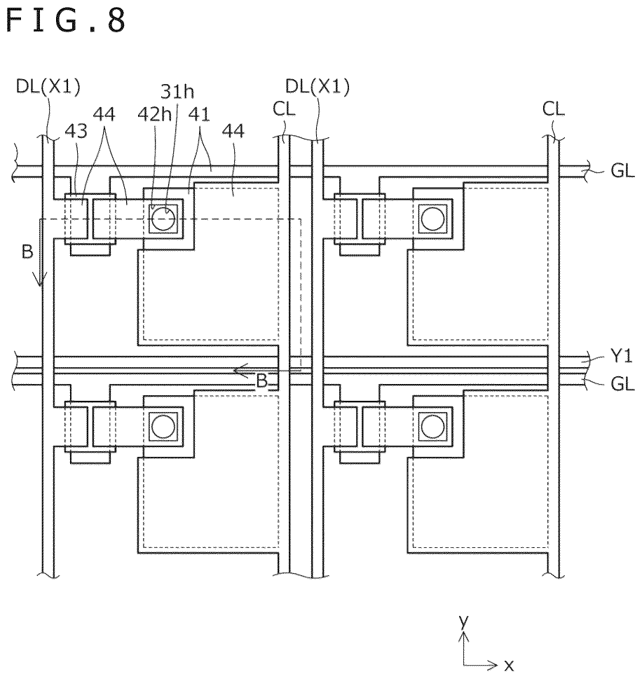

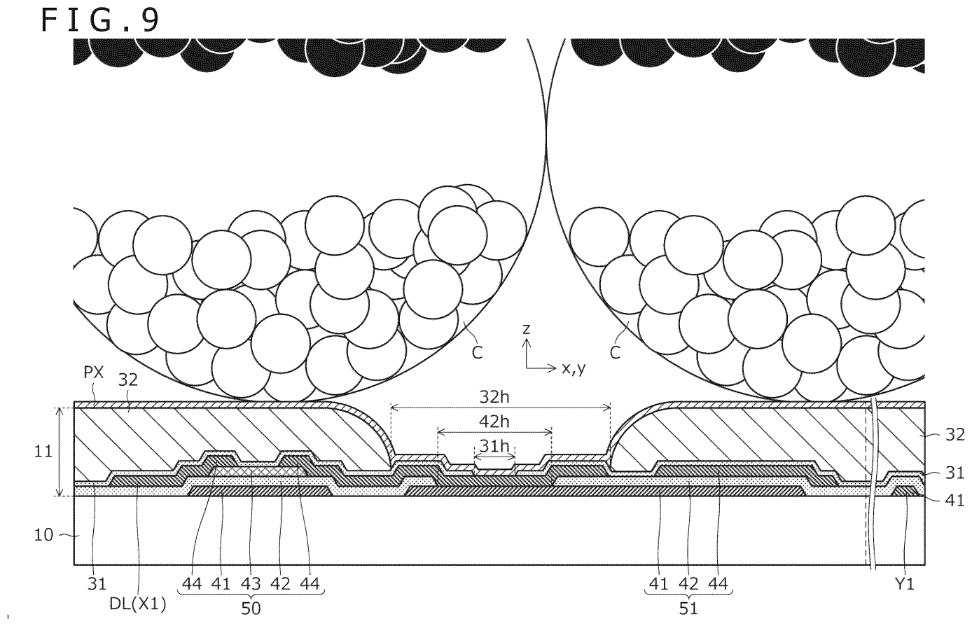

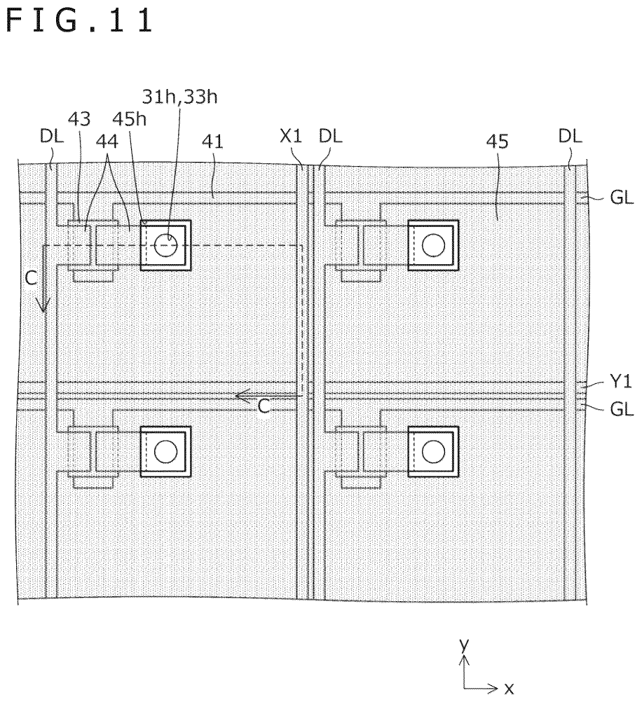

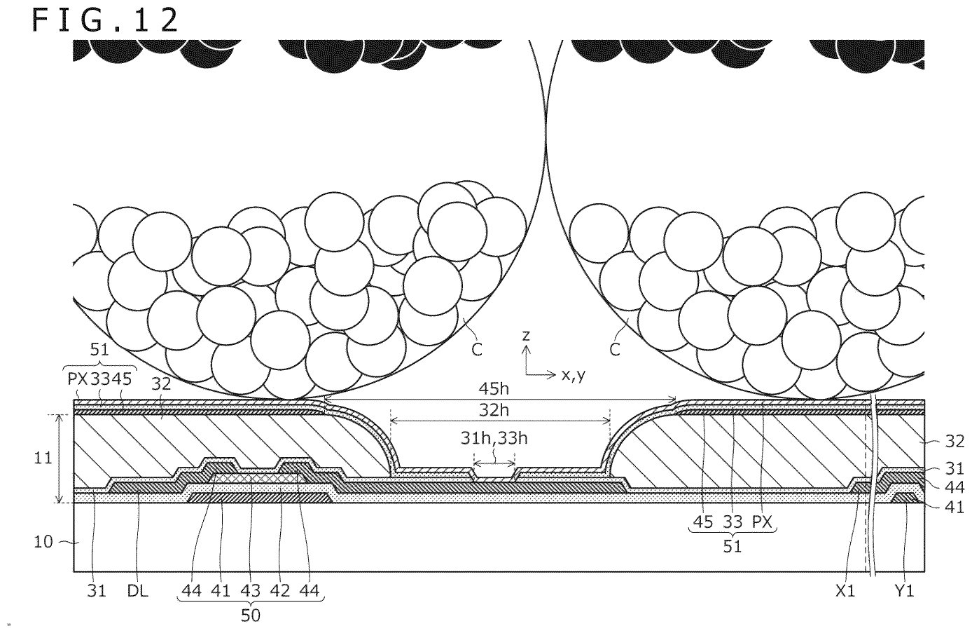

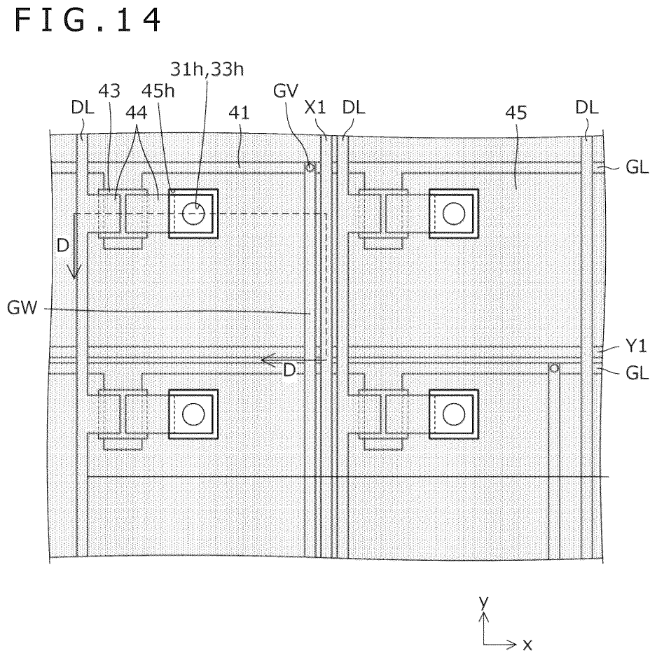

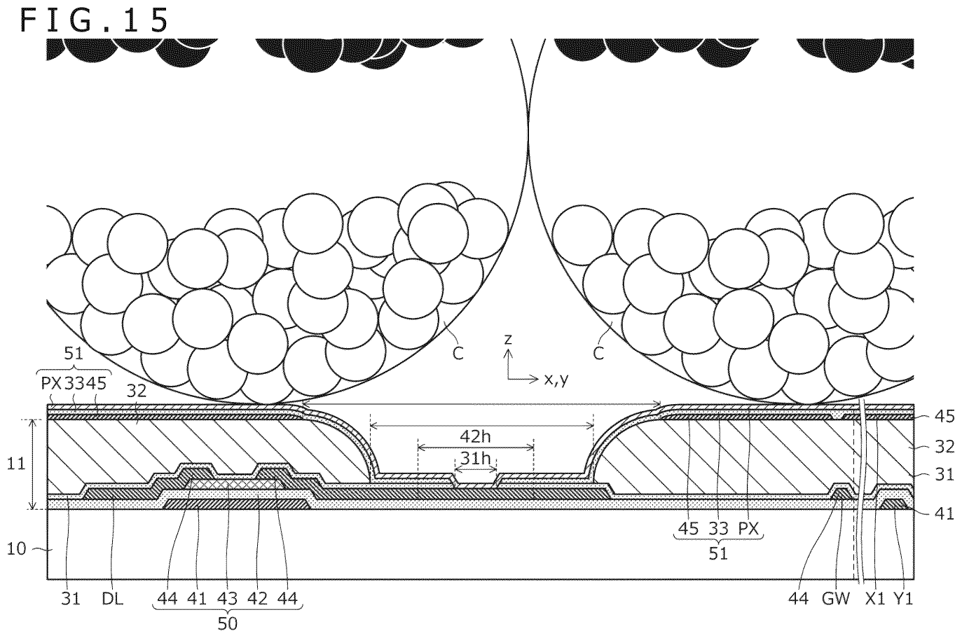

FIG. 6 is a diagram schematically depicting a planar structure of a portion corresponding to the circuit diagram of FIG. 3 in the circuit layer 11, and FIG. 7 is a schematic cross-sectional view of the backplane 20 corresponding to the line A-A depicted in FIG. 6. Since both FIG. 6 and FIG. 7 are schematic diagrams for understanding the structure, the configurations depicted in the respective drawings do not necessarily match each other. In FIG. 7, some of the reflective elements C in the reflective display layer 13 are also illustrated to facilitate understanding of the structure. These similarly apply to FIG. 8, FIG. 9, FIG. 11, FIG. 12, FIG. 14, and FIG. 15, which will be described later. Hereinafter, a structure inside the backplane 20 will be described in detail with reference to FIG. 6 and FIG. 7.

As depicted in FIG. 6 and FIG. 7, the circuit layer 11 has a gate conductor film 41, a gate insulating film 42, a semiconductor film 43, a source/drain conductor film 44, a passivation film 31, and an overcoat film 32.

The gate conductor film 41 is a metal film formed on the upper surface of the substrate 10 and configures the gate line GL, the control electrode of the pixel transistor 50, the first electrode of the storage capacitor 51, and the sensor electrode Y1. A portion of the gate conductor film 41 configuring the sensor electrode Y1 extends along the gate line GL.

The gate insulating film 42 is an insulating film formed so as to cover the upper surface of the gate conductor film 41 and configures a gate insulating film of the pixel transistor 50 and a dielectric arranged between the electrodes of the storage capacitor 51. In addition, the gate insulating film 42 has a contact hole 42h on the upper side of a portion of the gate conductor film 41 which is formed by extending a portion configuring the first electrode of the storage capacitor 51.

The semiconductor film 43 is an amorphous silicon film formed on the upper surface of the gate insulating film 42 at a position overlapping the control electrode of the pixel transistor 50 in plan view, and configures a channel layer of the pixel transistor 50.

The source/drain conductor film 44 is a metal film formed on the upper surfaces of the gate insulating film 42 and the semiconductor film 43 and configures the data line DL, the common potential line CL, the second electrode of the storage capacitor 51, the sensor electrode X1, and the first and second controlled electrodes of the pixel transistor 50. A portion of the source/drain conductor film 44 configuring the sensor electrode X1 extends between the data line DL and the storage capacitor 51 that are adjacent to each other in the x direction. In addition, the source/drain conductor film 44 also serves as an internal wire for connecting the second controlled electrode of the pixel transistor 50 to the first electrode of the storage capacitor 51 and the pixel electrode PX. The source/drain conductor film 44 is connected to a portion of the gate conductor film 41 configuring the first electrode of the storage capacitor 51, via the contact hole 42h described above.

The passivation film 31 is an insulating film for protecting the pixel transistor 50 and the storage capacitor 51 from dust and humidity and is formed on the upper side of the source/drain conductor film 44 so as to cover the entire surface. In the passivation film 31, a contact hole 31h having a diameter smaller than that of the contact hole 42h is provided at the center portion of the contact hole 42h.

The overcoat film 32 is also an insulating film for protection and is formed on the upper side of the passivation film 31 so as to cover the entire surface. In the overcoat film 32, a contact hole 32h having a diameter larger than that of the contact hole 42h is provided at the same position as the contact hole 31h. It should be noted that, while the diameter of each reflective element C is approximately 25 μm, the diameter of the contact hole 32h is usually 10 μm or less.

The pixel electrode PX includes a conductive film formed on the upper surface of the overcoat film 32. Unlike the common potential line CL and the like in the common electrode layer 14, the pixel electrode PX need not be transparent, but is usually formed of ITO as in the common potential line CL in the common electrode layer 14. This is to prevent oxidation of the pixel electrode PX in the manufacturing process of the reflective display 2. More specifically, the backplane 20 and the layers (front plane) above the reflective display layer 13 are usually formed in different processes, and then, both planes are bonded together. At this time, the pixel electrode PX is temporarily exposed to air. If the pixel electrode PX includes a metal film such as aluminum, the pixel electrode PX will be oxidized immediately after the exposure. Such oxidation can be avoided by forming the pixel electrode PX by using ITO.

As described above, according to the computer 1 of the present embodiment, the plurality of sensor electrodes X1 and the plurality of sensor electrodes Y1, which are used for detecting the position of the pen P according to the EMR system, are provided in the backplane 20 of the reflective display 2, and therefore, the reflective display 2 that is compatible with pen input based on the EMR system can be reduced in height.

Next, a computer 1 according to a second embodiment of the present disclosure will be described. The computer 1 according to the present embodiment is different from the computer 1 according to the first embodiment in that it uses the data lines DL also as the sensor electrodes X1 instead of providing the sensor electrodes X1 separately from the data lines DL. Other than that, the computer 1 according to the present embodiment is similar to the computer 1 according to the first embodiment, and therefore, the following description will focus on the differences from the computer 1 according to the first embodiment.

FIG. 8 is a diagram depicting a planar structure of a portion corresponding to the circuit diagram of FIG. 3 in a circuit layer 11 included in the computer 1 according to the present embodiment, and FIG. 9 is a schematic cross-sectional view of the backplane 20 corresponding to the line B-B depicted in FIG. 8. As depicted in FIG. 8 and FIG. 9, the circuit layer 11 according to the present embodiment is different from the circuit layer 11 according to the first embodiment in that it does not have the portion of the source/drain conductor film 44 configuring the sensor electrode X1.

FIG. 10 is a diagram depicting a positional relation of various types of wires included in a reflective display 2 according to the present embodiment. As depicted in FIG. 10, the reflective display 2 according to the present embodiment has switch groups 60 and 61 each including a plurality of switch elements.

The switch group 60 is a switch group including a plurality of switch elements each provided for one data line DL. Each of the switch elements is provided in the middle of the wire SL and is a single-pole double-throw switch which has a common terminal connected to an end portion of the corresponding data line DL on the terminal area TA side, one selection terminal connected to the host processor 3, and the other selection terminal connected to the sensor controller 4.

The switch group 61 is a switch group including a plurality of switch elements each provided for two adjacent data lines DL. Each of the switch elements is provided in the middle of the base electrode BE connected to end portions of corresponding data lines DL on the side far from the terminal area TA and is a single-pole single-throw switch which has one terminal connected to one of the corresponding two data lines DL and the other terminal connected to the other of the corresponding two data lines DL.

The sensor controller 4 according to the present embodiment uses linear conductors configuring the data lines DL, also as the sensor electrodes X1 in a time-division manner. Specifically, at a timing when the host processor 3 first drives the data lines DL, the sensor controller 4 sets each switch element configuring the switch group 60, to the host processor 3 side, and turns off each switch element configuring the switch group 61. Accordingly, the host processor 3 can drive the data lines DL normally. In contrast, at a timing (blank period) when the host processor 3 does not drive the data lines DL, the sensor controller 4 sets each switch element configuring the switch group 60, to the sensor controller 4 side, and turns on each switch element configuring the switch group 61. Accordingly, a loop coil is formed by the linear conductors configuring the data lines DL, and the sensor controller 4 can thus acquire the reception signals Rx from the pen P via the sensor electrodes X1 as in the first embodiment.

As described above, also according to the computer 1 of the present embodiment, the plurality of sensor electrodes X1 and the plurality of sensor electrodes Y1, which are used for detecting the position of the pen P according to the EMR system, are provided in the backplane 20 of the reflective display 2, and therefore, the reflective display 2 that is compatible with pen input based on the EMR system can be reduced in height.

In addition, according to the computer 1 of the present embodiment, the linear conductors configuring the data lines DL are also used as the sensor electrodes X1, which makes it possible to reduce the number of wires in the display area A1.

Next, a computer 1 according to a third embodiment of the present disclosure will be described. The computer 1 according to the present embodiment is different from the computer 1 according to the first embodiment in the structure of the storage capacitor 51. Other than that, the computer 1 according to the present embodiment is similar to the computer 1 according to the first embodiment, and therefore, the following description will focus on the differences from the computer 1 according to the first embodiment.

FIG. 11 is a diagram schematically depicting a planar structure of a portion corresponding to the circuit diagram of FIG. 3 in a circuit layer 11 included in the computer 1 according to the present embodiment, and FIG. 12 is a schematic cross-sectional view of the backplane 20 corresponding to the line C-C depicted in FIG. 11. As depicted in FIG. 11 and FIG. 12, the circuit layer 11 according to the present embodiment is different from the circuit layer 11 according to the first embodiment in that the electrodes of the storage capacitor 51 include the pixel electrode PX and a conductive film 45 formed on the upper surface of the overcoat film 32.

As can be understood by comparing FIG. 7 and FIG. 12 with each other, the gate conductor film 41 and the source/drain conductor film 44 according to the present embodiment do not have portions configuring the electrodes of the storage capacitor 51. In the present embodiment, however, the conductive film 45 is formed on the upper surface of the overcoat film 32, and a second passivation film 33 is further formed on the upper surface of the conductive film 45. The pixel electrode PX is formed on the upper surface of the passivation film 33. The storage capacitor 51 according to the present embodiment has the conductive film 45 thus formed, as the second electrode, and has the pixel electrode PX as the first electrode. The passivation film 33 serves as a dielectric arranged between the electrodes of the storage capacitor 51. A predetermined common potential (for example, ground potential) is supplied from the host processor 3 to the conductive film 45 as in the common potential line CL described in the first embodiment.

The conductive film 45 has a contact hole 45h having a diameter larger than that of the contact hole 32h of the overcoat film 32 at the same position as the contact hole 32h. In addition, the passivation film 33 has a contact hole 33h having substantially the same diameter as the contact hole 31h of the passivation film 31 at the same position as the contact hole 31h. The pixel electrode PX according to the present embodiment is connected to a portion of the source/drain conductor film 44 configuring the second controlled electrode of the pixel transistor 50, via the contact holes 31h and 46h.

Since the computer 1 according to the present embodiment is similar to the first embodiment in that the plurality of sensor electrodes X1 and the plurality of sensor electrodes Y1, which are used for detecting the position of the pen P according to the EMR system, are provided in the backplane 20 of the reflective display 2, the reflective display 2 that is compatible with pen input based on the EMR system can be reduced in height as in the first embodiment.

Next, a computer 1 according to a fourth embodiment of the present disclosure will be described. The computer 1 according to the present embodiment is different from the computer 1 according to the third embodiment in that the connection between each gate line GL and the host processor 3 is made via a gate wire GW extending in the display area A1. Other than that, the computer 1 according to the present embodiment is similar to the computer 1 according to the third embodiment, and therefore, the following description will focus on the differences from the computer 1 according to the third embodiment.

FIG. 13 is a diagram depicting a positional relation of various types of wires included in a reflective display 2 according to the present embodiment. In addition, FIG. 14 is a diagram schematically depicting a planar structure of a portion corresponding to the circuit diagram of FIG. 3 in a circuit layer 11 included in the computer 1 according to the present embodiment, and FIG. 15 is a schematic cross-sectional view of the backplane 20 corresponding to the line D-D depicted in FIG. 14.

The circuit layer 11 according to the present embodiment has the gate wire GW and a gate via conductor GV for each gate line GL. The gate via conductor GV is a via conductor penetrating the gate insulating film 42 and mutually connects the gate wire GW and the gate line GL corresponding to each other. The gate wire GW is a wire extending along the y direction from the position of the gate via conductor GV toward the terminal area TA side, and an end portion of the gate wire GW on the terminal area TA side is connected to the host processor 3 via the wire SL.

Since the computer 1 according to the present embodiment is similar to the third embodiment in that the plurality of sensor electrodes X1 and the plurality of sensor electrodes Y1, which are used for detecting the position of the pen P according to the EMR system, are provided in the backplane 20 of the reflective display 2, the reflective display 2 that is compatible with pen input based on the EMR system can be reduced in height as in the third embodiment.

In addition, according to the computer 1 of the present embodiment, the number of wires SL in the bezel area A2 in the lateral direction as viewed from the terminal area TA can be reduced, so that the bezel area A2 can be made narrower.

Next, a computer 1 according to a fifth embodiment of the present disclosure will be described. The computer 1 according to the present embodiment is different from the computer 1 according to the first embodiment in the use of the sensor electrodes X1 and Y1 for detecting the position of the pen P. Other than that, the computer 1 according to the present embodiment is similar to the computer 1 according to the first embodiment, and therefore, the following description will focus on the differences from the computer 1 according to the first embodiment.

FIG. 16 is a diagram depicting a positional relation of various types of wires included in a reflective display 2 according to the present embodiment. However, the gate lines GL, the data lines DL, and the common potential lines CL are omitted in the drawing. As depicted in FIG. 16, the reflective display 2 according to the present embodiment has switch groups 62 to 64 each including a plurality of switch elements.

The switch group 62 is a switch group including a plurality of switch elements each connecting two sensor electrodes Y1 to each other which are adjacent to each other with one sensor electrode Y1 interposed therebetween. Each of the switch elements is provided in the middle of the base electrode BE connected to first ends of corresponding sensor electrodes Y1 and is a single-pole single-throw switch which has one terminal connected to one of the corresponding two sensor electrodes Y1 and the other terminal connected to the other of the corresponding two sensor electrodes Y1.

The switch group 63 is a switch group including a plurality of switch elements each connecting two adjacent sensor electrodes Y1 to each other which are not connected to the switch group 62. Each of the switch elements is provided in the middle of the base electrode BE connected to second ends of corresponding sensor electrodes Y1 and is a single-pole single-throw switch which has one terminal connected to one of the corresponding two sensor electrodes Y1 and the other terminal connected to the other of the corresponding two sensor electrodes Y1.

The switch group 64 is a switch group including a plurality of switch elements each connecting two adjacent sensor electrodes X1 to each other. Each of the switch elements is provided in the middle of the base electrode BE connected to end portions of corresponding sensor electrodes X1 on the side far from the terminal area TA and is a single-pole single-throw switch which has one terminal connected to one of the corresponding two sensor electrodes X1 and the other terminal connected to the other of the corresponding two sensor electrodes X1.

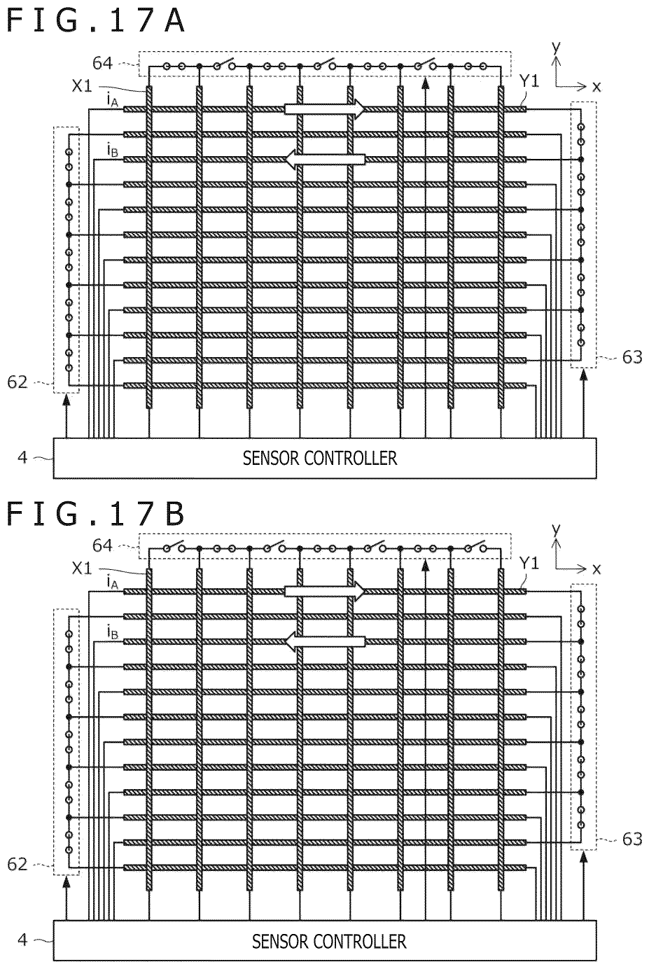

FIGS. 17A and 17B are diagrams for explaining processing performed by a sensor controller 4 according to the present embodiment to detect the position of the pen P by using the sensor electrodes X1 and Y1. When starting the position detection processing, the sensor controller 4 according to the present embodiment first turns on all the switch elements configuring the switch groups 62 and 63, as depicted in FIG. 17A. Then, the sensor controller 4 turns on every two switch elements configuring the switch group 64 and selects one sensor electrode Y1 located at the farthest end in the y direction, from among a plurality of sensor electrodes Y1 excluding one sensor electrode Y1 at each of opposite ends in the y direction. Turning on every two switch elements configuring the switch group 64 forms a plurality of loop coils. The sensor controller 4 has the differential amplifier 4a, which is depicted in FIG. 5, for each loop coil thus formed, and opposite ends of the formed loop coil are connected to the respective two input terminals of the corresponding differential amplifier 4a.

Subsequently, the sensor controller 4 supplies the alternating current i_{A} to one end of one sensor electrode Y1 adjacent to the selected sensor electrode Y1 on one side and supplies the alternating current i_{B} to one end of one sensor electrode Y1 adjacent to the selected sensor electrode Y1 on the other side. The details of the alternating currents i_{A} and i_{B} are as described in the first embodiment. Accordingly, a change in magnetic flux occurs above the selected sensor electrode Y1. Then, when the inductor of the pen P enters the magnetic flux (alternating magnetic field) that changes, electromagnetic induction action occurs between the sensor electrode Y1 and the inductor, and a change in current is generated in the inductor. As a result, an alternating magnetic field is transmitted from the pen P, and an electromotive force is generated in the sensor electrode X1 located nearby. A current is generated in each loop coil by the electromotive force thus generated and is supplied to the sensor controller 4 via the differential amplifier 4a. The sensor controller 4 acquires the current thus supplied from the differential amplifier 4a immediately after supplying the alternating currents i_{A} and i_{B} to the sensor electrodes Y1 for a predetermined period of time, as a reception signal Rx from the pen P which corresponds to each loop coil.

Next, as depicted in FIG. 17B, the sensor controller 4 switches on/off of the plurality of switch elements configuring the switch group 64 and connects opposite ends of the newly formed loop coil to the respective two input terminals of the corresponding differential amplifier 4a. Then, by performing the processing similar to that described above, the sensor controller 4 acquires the reception signal Rx from the pen P which corresponds to each loop coil.

The sensor controller 4 repeatedly executes the above processing while shifting the sensor electrodes Y1 to be selected, one by one. When the selection of all the sensor electrodes Y1 and the subsequent processing are finished, the sensor controller 4 acquires, for each sensor electrode Y1, the reception signal Rx received at each loop coil. The sensor controller 4 derives the distribution, in the operation surface 1a, of the signal intensities of a plurality of acquired reception signals Rx and then derives the position of the pen P on the basis of the result.

Since the computer 1 according to the present embodiment is similar to the first embodiment in that the plurality of sensor electrodes X1 and the plurality of sensor electrodes Y1, which are used for detecting the position of the pen P according to the EMR system, are provided in the backplane 20 of the reflective display 2, the reflective display 2 that is compatible with pen input based on the EMR system can be reduced in height as in the first embodiment.

In addition, according to the computer 1 of the present embodiment, the reception signals Rx from the pen P which correspond to the plurality of loop coils can be acquired at a time, and thus, the position of the pen P can be derived at a high frequency.

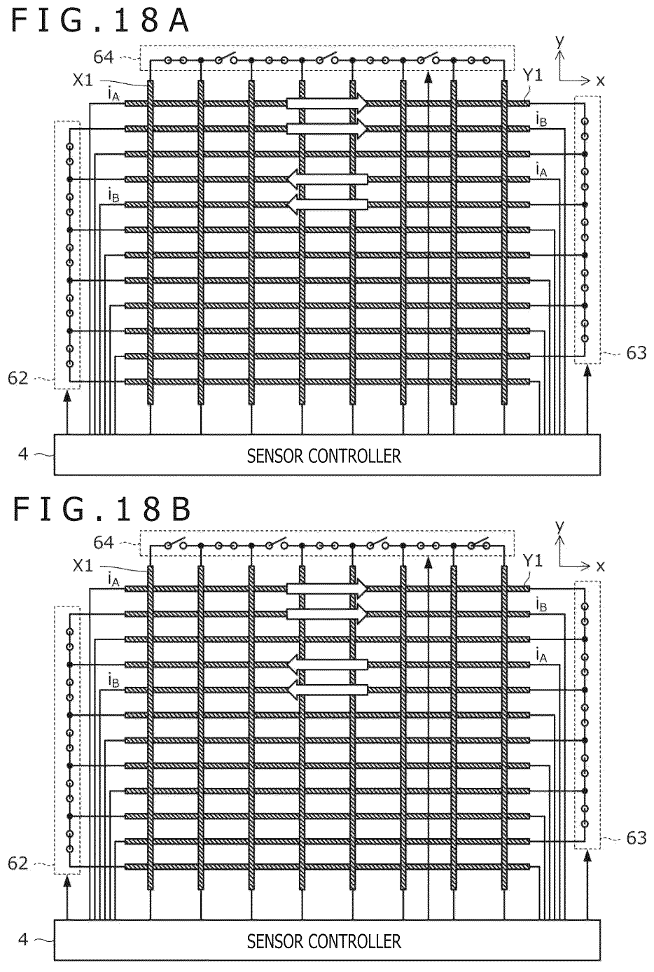

FIGS. 18A and 18B are diagrams for explaining processing performed by a sensor controller 4 according to a first modified example of the present embodiment. The sensor controller 4 according to the present modified example is different from the sensor controller 4 according to the present embodiment in that it supplies the alternating current i_{A} to one end of each of two sensor electrodes Y1 which are adjacent to the selected sensor electrode Y1 on one side, and supplies the alternating current i_{B} to one end of each of two sensor electrodes Y1 which are adjacent to the selected sensor electrode Y1 on the other side. The method of supplying the alternating currents i_{A} and i_{B} is similar to that described in the first embodiment. Accordingly, it is possible to increase the transmission intensity of the alternating magnetic field generated above the sensor electrode Y1.

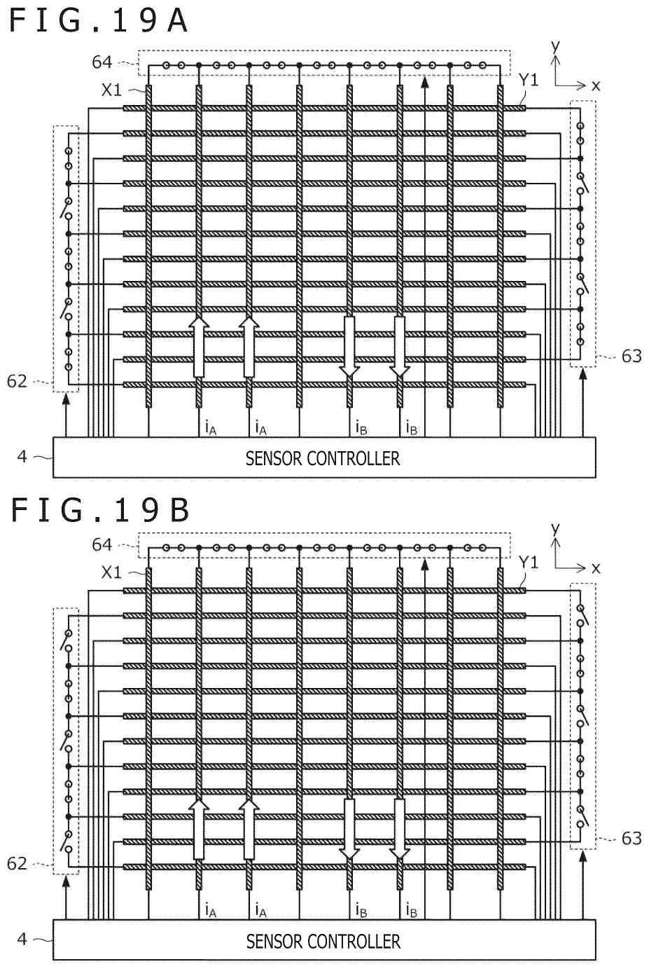

FIGS. 19A and 19B are diagrams for explaining processing performed by a sensor controller 4 according to a second modified example of the present embodiment. The sensor controller 4 according to the present modified example is different from the sensor controller 4 according to the present embodiment in that an alternating magnetic field is transmitted from the sensor electrode X1 and that the alternating magnetic field transmitted from the pen P is received at the sensor electrode Y1.

Specifically, when starting the position detection processing, the sensor controller 4 according to the present embodiment first turns on all the switch elements configuring the switch group 64, as depicted in FIG. 19A. Then, the sensor controller 4 turns on every two switch elements included in each of the switch groups 62 and 63 and selects one sensor electrode X1 located at the farthest end in the x direction, from among a plurality of sensor electrodes X1 excluding two sensor electrodes X1 at each of opposite ends in the x direction. Turning on every two switch elements included in each of the switch groups 62 and 63 forms a plurality of loop coils. The sensor controller 4 has the differential amplifier 4a, which is depicted in FIG. 5, for each loop coil thus formed, and opposite ends of the formed loop coil are connected to the respective two input terminals of the corresponding differential amplifier 4a.

Subsequently, the sensor controller 4 supplies the alternating current i_{A} to one end of each of two sensor electrodes X1 adjacent to the selected sensor electrode X1 on one side and supplies the alternating current i_{B} to one end of each of two sensor electrodes X1 adjacent to the selected sensor electrode X1 on the other side. Accordingly, a change in magnetic flux occurs above the selected sensor electrode X1. Then, when the inductor of the pen P enters the magnetic flux (alternating magnetic field) that changes, electromagnetic induction action occurs between the sensor electrode X1 and the inductor, and a change in current is generated in the inductor. As a result, an alternating magnetic field is transmitted from the pen P, and an electromotive force is generated in the sensor electrode Y1 located nearby. A current is generated in each loop coil by the electromotive force thus generated and is supplied to the sensor controller 4 via the differential amplifier 4a. The sensor controller 4 acquires the current thus supplied from the differential amplifier 4a immediately after supplying the alternating currents i_{A} and i_{B} to the sensor electrodes X1 for a predetermined period of time, as a reception signal Rx from the pen P which corresponds to each loop coil.

Next, as depicted in FIG. 19B, the sensor controller 4 switches on/off of the plurality of switch elements configuring the switch groups 62 and 63 and connects opposite ends of the newly formed loop coil to the respective two input terminals of the corresponding differential amplifier 4a. Then, by performing the processing similar to that described above, the sensor controller 4 acquires the reception signal Rx from the pen P which corresponds to each loop coil.

The sensor controller 4 repeatedly executes the above processing while shifting the sensor electrodes X1 to be selected, one by one. When the selection of all the sensor electrodes X1 and the subsequent processing are finished, the sensor controller 4 acquires, for each sensor electrode X1, the reception signal Rx received at each loop coil. The sensor controller 4 derives the distribution, in the operation surface 1a, of the signal intensities of a plurality of acquired reception signals Rx and then derives the position of the pen P on the basis of the result. In this manner, also according to the present modified example, the position of the pen P can be derived as in the sensor controller 4 according to the present embodiment. It is obvious that the sensor controller 4 according to the present modified example may be configured to supply the alternating current i_{A} to one end of one sensor electrode Y1 adjacent to the selected sensor electrode Y1 on one side and to supply the alternating current i_{B} to one end of one sensor electrode Y1 adjacent to the selected sensor electrode Y1 on the other side, as in the sensor controller 4 according to the present embodiment.

Although the preferred embodiments of the present disclosure have been described above, it is obvious that the present disclosure is not limited to such embodiments in any way and can be carried out in various modes without departing from the gist thereof.

For example, while the sensor electrodes X1 and Y1 are arranged in the circuit layer 11 in each of the above-described embodiments, arranging the sensor electrodes X1 and Y1 in another layer can also reduce the height of the reflective display 2 that is compatible with pen input based on the EMR system, as in each of the above-described embodiments. Hereinafter, specific examples thereof will be described.

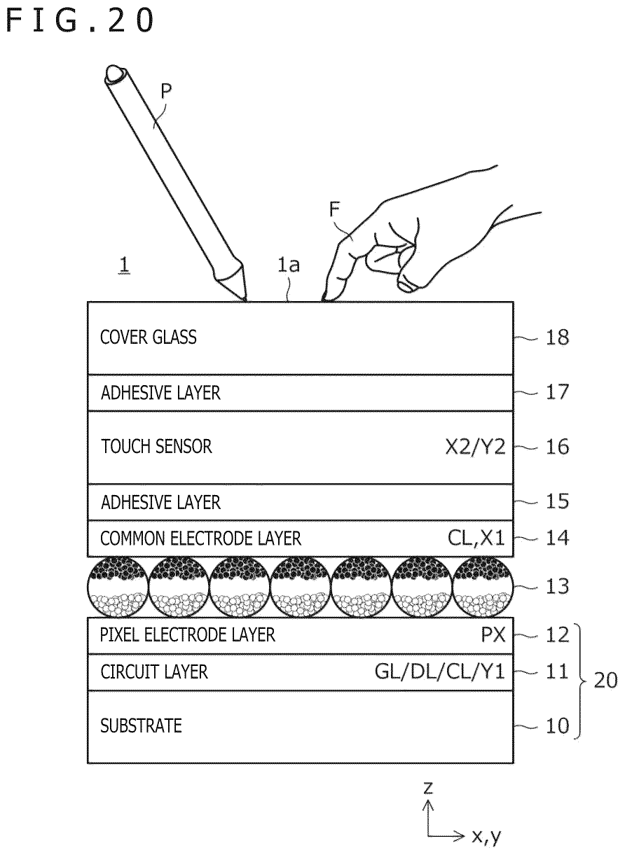

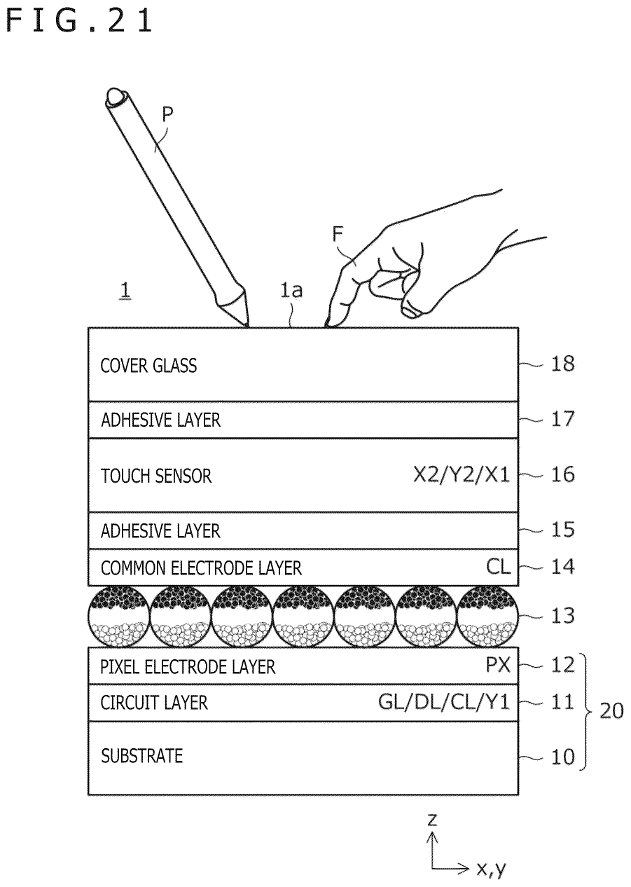

FIG. 20 and FIG. 21 are diagrams each depicting an example of a layer structure of the reflective display 2 in the case where the sensor electrodes X1 and Y1 are arranged in a layer other than the circuit layer 11.

In the example depicted in FIG. 20, the sensor electrodes X1 are provided in the common electrode layer 14. In this case, the sensor electrodes X1 may be provided separately from the common potential lines CL in the common electrode layer 14, or the common potential lines CL may be used as the sensor electrodes X1 in a time-division manner. In addition, instead of the sensor electrodes X1, the sensor electrodes Y1 may be provided in the common electrode layer 14. Even in this case, the sensor electrodes Y1 may be provided separately from the common potential lines CL in the common electrode layer 14, or the common potential lines CL may be used as the sensor electrodes Y1 in a time-division manner.

In the example depicted in FIG. 21, the sensor electrodes X1 are provided in the touch sensor 16. In this case, the sensor electrodes X1 may be provided separately from the sensor electrodes X2, or the sensor electrodes X2 may be used as the sensor electrodes X1 in a time-division manner. In addition, instead of the sensor electrodes X1, the sensor electrodes Y1 may be provided in the touch sensor 16. Even in this case, the sensor electrodes Y1 may be provided separately from the sensor electrodes Y2, or the sensor electrodes Y2 may be used as the sensor electrodes Y1 in a time-division manner.

In addition, in each of the above-described embodiments, either one of the sensor electrodes X1 and Y1 is used for transmitting the alternating magnetic field, and the other is used for receiving the reception signal Rx, but both of them can also be used for receiving the reception signal Rx.

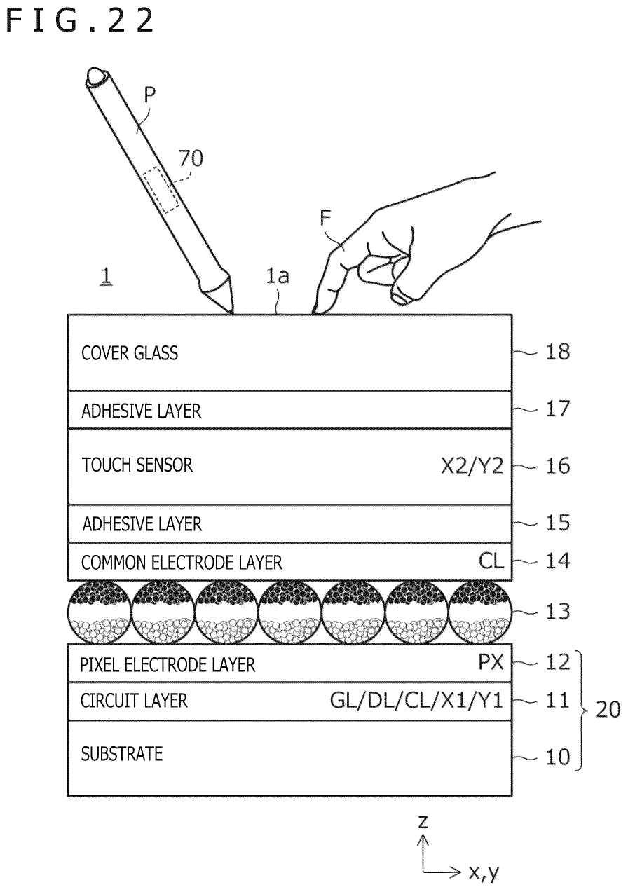

FIG. 22 is a diagram depicting a layer structure of the reflective display 2 in the case where both of the sensor electrodes X1 and Y1 are used for receiving the reception signal Rx. As depicted in FIG. 22, a battery 70 is provided in the pen P in the present modified example, and the pen P transmits an alternating magnetic field from the inductor by using electric power supplied from battery 70. The sensor controller 4 may derive the position of the pen P by forming a loop coil by each of the sensor electrodes X1 and Y1 and receiving, at each loop coil, the alternating magnetic field transmitted by the pen P.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A reflective display, comprising:
a cover layer that has an operation surface on which a position indicator including an inductor is operated;
a reflective display layer that includes a plurality of reflective elements each of which reflects, with a set gradation, light incident from the cover layer;
a backplane that is provided at a position farther than the reflective display layer as viewed from the operation surface; and
a common electrode layer that includes a common electrode provided between the cover layer and the reflective display layer, wherein
the backplane has, in a display area overlapping the plurality of reflective elements in plan view,
a plurality of pixel electrodes arranged in a matrix along a first direction and a second direction intersecting the first direction,
a plurality of data lines each extending along the first direction, and
a plurality of first electromagnetic induction sensor electrodes each extending along the first direction, and
the plurality of first electromagnetic induction sensor electrodes are used for detecting a position of the position indicator in the operation surface by generating electromagnetic induction action with the inductor.

2. The reflective display according to claim 1, wherein
the common electrode layer has, in the display area, a plurality of second electromagnetic induction sensor electrodes each extending along the second direction, and
the plurality of second electromagnetic induction sensor electrodes are used for detecting the position of the position indicator in the operation surface by generating electromagnetic induction action with the inductor.

3. The reflective display according to claim 1, comprising:
a touch sensor that is provided between the cover layer and the common electrode layer, wherein
the touch sensor has, in the display area, a plurality of second electromagnetic induction sensor electrodes each extending along the second direction.

4. The reflective display according to claim 1, wherein
each of the plurality of first electromagnetic induction sensor electrodes generates electromagnetic induction action with the inductor when an electromotive force corresponding to a change in magnetic flux generated by a change in current flowing in the inductor is generated.

5. The reflective display according to claim 1, wherein
the backplane has, in the display area,
a plurality of gate lines each extending along the second direction, and
a plurality of second electromagnetic induction sensor electrodes each extending along the second direction, and
the plurality of second electromagnetic induction sensor electrodes are used for detecting the position of the position indicator in the operation surface by generating electromagnetic induction action with the inductor.

6. The reflective display according to claim 5, wherein
the backplane has, in the display area, a plurality of pixel transistors provided to correspond to the respective pixel electrodes, and
each of the plurality of pixel transistors has
a control electrode connected to any one of the plurality of gate lines,
one controlled electrode connected to any one of the plurality of data lines, and
another controlled electrode connected to a corresponding one of the pixel electrodes.

7. The reflective display according to claim 6, wherein
the backplane has, in the display area, a plurality of storage capacitors provided to correspond to the respective pixel electrodes, and
each of the plurality of storage capacitors has one electrode connected to a corresponding one of the pixel electrodes.

8. The reflective display according to claim 7, wherein
each of the plurality of first electromagnetic induction sensor electrodes extends between the data line and the storage capacitor that are adjacent to each other in the second direction.

9. The reflective display according to claim 8, wherein
the number of the plurality of first electromagnetic induction sensor electrodes is smaller than the number of the data lines.

10. The reflective display according to claim 7, wherein
the backplane has
an insulating film that covers the plurality of data lines, and
a plurality of conductive films that are each provided between a corresponding one of the plurality of pixel electrodes and the insulating film, and
each of the storage capacitors has another electrode including a corresponding one of the conductive films.

11. The reflective display according to claim 5, wherein
corresponding ones of the plurality of second electromagnetic induction sensor electrodes are connected to each other by a base electrode provided at end portions thereof.

12. The reflective display according to claim 11, wherein
the base electrode is arranged in an area outside the display area in plan view.

13. The reflective display according to claim 5, wherein
each of the plurality of second electromagnetic induction sensor electrodes generates electromagnetic induction action with the inductor when an alternating current being supplied from a sensor controller and flowing therethrough causes a change in magnetic flux.

14. The reflective display according to claim 5, wherein
each of the plurality of first electromagnetic induction sensor electrodes generates electromagnetic induction action with the inductor when an alternating current being supplied from a sensor controller and flowing therethrough causes a change in magnetic flux.

15. The reflective display according to claim 14, wherein
each of the plurality of second electromagnetic induction sensor electrodes generates electromagnetic induction action with the inductor when an electromotive force corresponding to a change in magnetic flux generated by a change in current flowing in the inductor is generated.

16. The reflective display according to claim 5, wherein
either a first end or a second end of each of the plurality of gate lines is connected to a routing wire such that a connection of the first end and a connection of the second end are alternately made when viewed in the first direction.

17. The reflective display according to claim 5, wherein
each of the plurality of gate lines is connected to a routing wire in the display area.

18. A reflective display, comprising:
a cover layer that has an operation surface on which a position indicator including an inductor is operated;
a reflective display layer that includes a plurality of reflective elements each of which reflects, with a set gradation, light incident from the cover layer;
a backplane that is provided at a position farther than the reflective display layer as viewed from the operation surface; and
a common electrode that is provided between the cover layer and the reflective display layer, wherein
the backplane has, in a display area overlapping the plurality of reflective elements in plan view,
a plurality of pixel electrodes arranged in a matrix along a first direction and a second direction intersecting the first direction,
a plurality of gate lines each extending along the second direction, and
a plurality of second electromagnetic induction sensor electrodes each extending along the second direction, and
the plurality of second electromagnetic induction sensor electrodes are used for detecting a position of the position indicator in the operation surface by generating electromagnetic induction action with the inductor.

19. A reflective display, comprising:
a cover layer that has an operation surface on which a position indicator including an inductor is operated;
a reflective display layer that includes a plurality of reflective elements each of which reflects, with a set gradation, light incident from the cover layer;
a backplane that is provided at a position farther than the reflective display layer as viewed from the operation surface; and
a common electrode that is provided between the cover layer and the reflective display layer, wherein
the backplane has, in a display area overlapping the plurality of reflective elements in plan view, a plurality of pixel electrodes arranged in a matrix along a first direction and a second direction intersecting the first direction and a plurality of linear conductors each extending along the first direction, and
the plurality of linear conductors are used, in a time-division manner, as either a plurality of data lines used for supplying data signals to the pixel electrodes or a plurality of first electromagnetic induction sensor electrodes used for detecting a position of the position indicator in the operation surface by generating electromagnetic induction action with the inductor.
